(19) United States
(12) Patent Application Publication
(10) Pub. No.: US 2025/0081538 A1
(43) Pub. Date: Mar. 6, 2025

(54) THIN FILM TRANSISTOR, DISPLAY PANEL, AND DISPLAY APPARATUS

(71) Applicants: Hefei Visionox Technology Co., Ltd., Hefei (CN); Yungu (Gu’an) Technology Co., Ltd., Langfang (CN)

(72) Inventors: Guowen YAN, Hefei (CN); Dejian WANG, Hefei (CN); Xiaoqi SUN, Hefei (CN); Lin XU, Hefei (CN); Fa-Hsyang CHEN, Hefei (CN)

(73) Assignees: Hefei Visionox Technology Co., Ltd., Hefei (CN); Yungu (Gu’an) Technology Co., Ltd., Langfang (CN)

(21) Appl. No.: 18/953,066

(22) Filed: Nov. 20, 2024

(30) Foreign Application Priority Data
Nov. 30, 2023 (CN) 202311660490.3

(51) Int. Cl. H01L 29/786

(52) U.S. Cl. CPC H10D 30/6755; H10D 30/6733

(57) ABSTRACT

The disclosure relates to the field of display technologies, and in particular, to a thin film transistor, a display panel, and a display apparatus. The thin film transistor includes: an active layer provided on a substrate. The active layer includes a first semiconductor layer, a first barrier layer, and a second semiconductor layer stacked in sequence. The first semiconductor layer is located on a side, away from the substrate, of the second semiconductor layer, and a mobility rate of the first semiconductor layer is less than a mobility rate of the second semiconductor layer. A double channel is formed by providing the first barrier layer provided between the first semiconductor layer and the second semiconductor layer, so as to make a threshold voltage Vth positive and improve the mobility rate of the thin film transistor, so that a greater processing Margin may be accommodated, thereby ensuring stability of a device.

### CROSS-REFERENCE TO RELATED APPLICATIONS

This application claims priority to Chinese Patent Application No. 202311660490.3, filed on Nov. 30, 2023, which is hereby incorporated by reference in its entirety.

### TECHNICAL FIELD

The present disclosure relates to the field of display technologies, and in particular, to a thin film transistor, a display panel, and a display apparatus.

### BACKGROUND

In recent years, with rapid development and application of information technology, wireless mobile communication, and information appliances, people's dependence on electronic products is increasing, leading to vigorous development of various display technologies and display apparatus.

A pixel circuit of an organic light emitting diode (OLED) display panel requires a plurality of thin film transistors (TFTs). The thin film transistor is generally used as a switching element or a driving element to control a pixel. However, currently, the thin film transistor in conventional technology still has problems such as low reliability and low stability.

### SUMMARY

In view of this, embodiments of the present disclosure provide a thin film transistor, a display panel, and a display apparatus, so as to solve a problem of low reliability and low stability of a thin film transistor in conventional technology.

In a first aspect, an embodiment of the present disclosure provides a thin film transistor, and the thin film transistor includes: a substrate; and an active layer provided on the substrate, where the active layer includes a first semiconductor layer, a first barrier layer, and a second semiconductor layer stacked in sequence, the first semiconductor layer is located on a side, away from the substrate, of the second semiconductor layer, and a mobility rate of the first semiconductor layer is less than a mobility rate of the second semiconductor layer; and the thin film transistor is a top gate structure or a dual-gate structure.

In a second aspect, an embodiment of the present disclosure provides a thin film transistor and the thin film transistor includes: a substrate; and an active layer provided on the substrate, where the active layer includes a first semiconductor layer, a first barrier layer, and a second semiconductor layer stacked in sequence, the first semiconductor layer is located on a side, away from the substrate, of the second semiconductor layer, and a mobility rate of the second semiconductor layer is less than a mobility rate of the first semiconductor layer; and the thin film transistor is a bottom gate structure.

In a third aspect, an embodiment of the present disclosure provides a display panel, and the display panel includes: a substrate base; and a plurality of pixel units disposed on the substrate base, where the pixel unit includes a pixel circuit, and the pixel circuit includes the thin film transistor mentioned in the first aspect or the second aspect.

In a fourth aspect, an embodiment of the present disclosure provides a display apparatus, and the display apparatus includes the display panel mentioned in the third aspect.

### BRIEF DESCRIPTION OF THE DRAWINGS

FIG. 1 is a schematic structural diagram of a thin film transistor according to an embodiment of the present disclosure.

FIG. 2 is a schematic structural diagram of a thin film transistor according to another embodiment of the present disclosure.

FIG. 3 is a schematic structural diagram of a thin film transistor according to still another embodiment of the present disclosure.

FIG. 4 is a schematic structural diagram of an active layer according to an embodiment of the present disclosure.

FIG. 5 is a schematic structural diagram of an active layer according to another embodiment of the present disclosure.

FIG. 6 is a schematic structural diagram of an active layer according to still another embodiment of the present disclosure.

FIG. 7 is a schematic structural diagram of an active layer according to still another embodiment of the present disclosure.

### DETAILED DESCRIPTION OF THE EMBODIMENTS

Technical solutions in the embodiments of the present disclosure are described clearly and completely below with reference to the accompanying drawings in the embodiments of the present disclosure. Obviously, the described embodiments are only part of the embodiments of the present disclosure, not all of them. substrated on the embodiments in the present disclosure, all other embodiments obtained by ordinary technicians in the art without doing creative work belong to the protection scope of the present disclosure.

A thin film transistor is a core component of panel display. Any active matrix of the panel display depends on control and drive of the thin film transistor. An amorphous oxide semiconductor (AOS), such as indium gallium zinc oxide (IGZO), is widely used as a channel material of the thin film transistor in the panel display due to characteristics of high mobility rate, large area uniformity, low-temperature processability and optical transparency.

An IGZO semiconductor mainly includes indium (In), gallium (Ga), zinc (Zn) and doped elements. With an increase of a content of In, a mobility rate of a device will be greater, but a threshold voltage (Vth) of the device will become smaller. Therefore, it is difficult to maintain a high mobility rate and a positive threshold voltage at the same time. In an oxide device with a low-mobility/high-mobility multilayer, a semiconductor layer of a high mobility rate and a semiconductor layer of a low mobility rate may be stacked in layers to form a double channel, thereby achieving a positive Vth and improving the mobility rate at the same time. However, during preparation process of a high-mobility semiconductor layer and a low-mobility semiconductor layer, elements are easy to diffuse, so that a low mobility interface may be unclear and a multi-channel effect may not be effectively formed.

In view of this, the present disclosure provides a thin film transistor, a display panel and a display apparatus to solve a problem of low reliability and low stability of a thin film transistor.

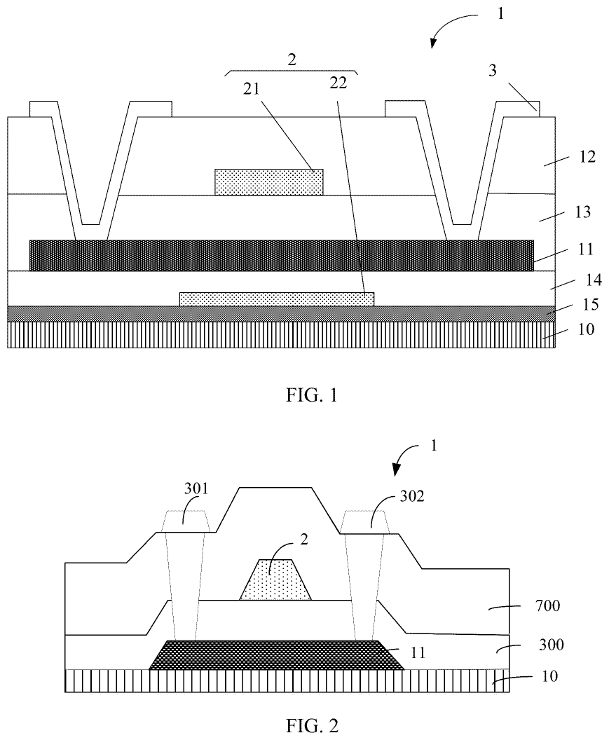

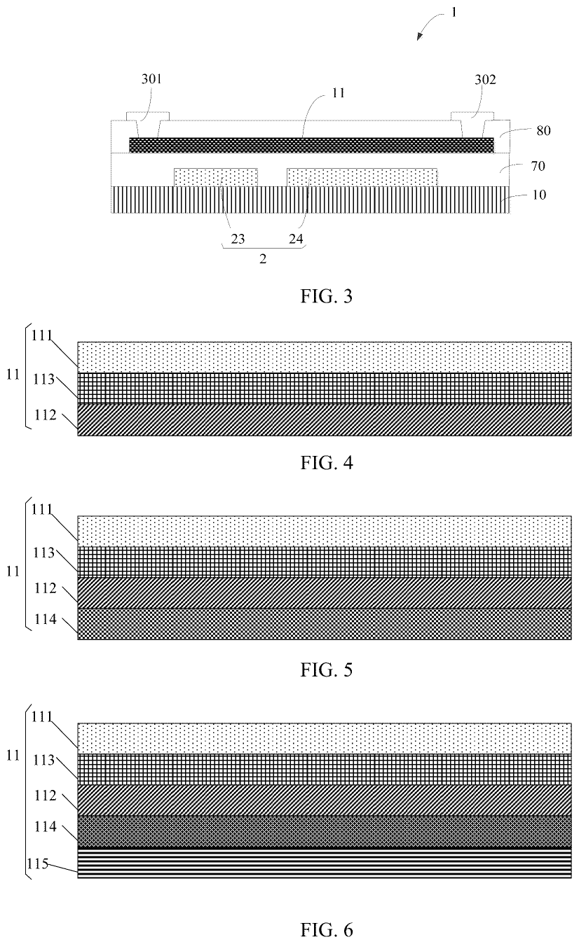

FIG. 1 is a schematic structural diagram of a thin film transistor according to an embodiment of the present disclosure. FIG. 2 is a schematic structural diagram of a thin film transistor according to another embodiment of the present disclosure. FIG. 3 is a schematic structural diagram of a thin film transistor according to still another embodiment of the present disclosure. FIG. 4 is a schematic structural diagram of an active layer according to an embodiment of the present disclosure. As shown in FIGS. 1 to 4, the thin film transistor 1 includes: a substrate 10; and an active layer 11 disposed on the substrate 10. The active layer 11 includes a first semiconductor layer 111, a first barrier layer 113, and a second semiconductor layer 112 stacked in sequence. The first semiconductor layer 111 is located on a side, away from the substrate 10, of the second semiconductor layer 112. A mobility rate of the first semiconductor layer 111 is less than a mobility rate of the second semiconductor layer 112. The first barrier layer 113 is disposed between the first semiconductor layer 111 and the second semiconductor layer 112.

Specifically, as shown in FIG. 1, the thin film transistor 1 is a dual-gate structure. The thin film transistor 1 includes an active layer 11, a gate electrode 2, and source-drain electrodes 3 formed on the active layer 11. The source-drain electrodes 3 are spaced apart from each other. The gate electrode 2 includes a top gate 21 disposed on a side, away from the substrate 10, of the active layer 11 and a bottom gate 22 disposed on a side, close to the substrate 10, of the active layer 11. The source-drain electrode 3 is disposed on the side, away from the substrate 10, of the active layer 11. The thin film transistor 1 may further include an inter-layer dielectric layer 12, a first gate insulation layer 13, and a second gate insulation layer 14, so as to define various structures of the thin film transistor 1. The first gate insulation layer 13 is located between the top gate 21 and the active layer 11 to separate the top gate 21 and the active layer 11. The second gate insulation layer 14 is located between the bottom gate 22 and the active layer 11 to separate the bottom gate 22 and the active layer 11. The inter-layer dielectric layer 12 is located between a source-drain electrode layer (including the source-drain electrode 3) and the active layer 11 to separate the source-drain electrode layer and the active layer 11.

As shown in FIG. 1, the thin film transistor 1 may further include a buffer layer 15 located between the substrate 10 and the active layer 11, and the buffer layer 15 is configured to block a harmful ion invading from the substrate 10 to the active layer 11.

As shown in FIG. 2, the thin film transistor 1 is a top gate structure. The thin film transistor 1 includes a substrate 10, an active layer 11, a gate insulation layer 300 and a gate electrode 2. The active layer 11 is formed on the substrate 10. The gate insulation layer 300 is located on a side, away from the substrate 10, of the active layer 11. The gate electrode 2 is located on a side, away from the active layer 11, of the gate insulation layer 300. The thin film transistor 1 may further include a source electrode 301 and a drain electrode 302. The source electrode 301 and the drain electrode 302 are connected to the active layer 11 respectively. The source electrode 301 and the drain electrode 302 of the top gate structure are located on a side, away from the active layer 11, of the gate electrode 2. Optionally, an insulation layer 700 is further disposed between the source electrode 301, the drain electrode 302 and the gate electrode 2. Optionally, the source electrode 301 and the drain electrode 302 are disposed in a same layer.

As shown in FIG. 3, the thin film transistor 1 is a bottom gate structure. The thin film transistor 1 includes a substrate 10, an active layer 11, a source electrode 301 and a drain electrode 302. The active layer 11 is located on the substrate 10. The source electrode 301 and the drain electrode 302 are located on a side, away from the substrate 10, of the active layer 11. The gate electrode 2 is located on a side, close to the substrate 10, of the active layer 11. The gate electrode 2 includes a first gate portion 23 and a second gate portion 24 insulated from each other. An inter-layer insulation layer 70 may be disposed between the active layer 11 and the gate electrode 2. Alternatively, the inter-layer insulation layer 70 is further filled in a gap between the first gate portion 23 and the second gate portion 24. The active layer 11 may be covered with an external dielectric layer 80.

Each of the active layers 11 in the thin film transistors shown in FIGS. 1 to 3 includes a first semiconductor layer 111, a first barrier layer 113, and a second semiconductor layer 112 stacked in sequence. In the dual-gate structure, the first semiconductor layer 111 in the active layer 11 is a low-mobility film layer, the second semiconductor layer 112 is a the high-mobility film layer, and the first barrier layer 113 is disposed between the low-mobility film layer and the high-mobility film layer. In the bottom gate structure, the first semiconductor layer 111 in the active layer 11 is a high-mobility film layer, the second semiconductor layer 112 is a low-mobility film layer, and the first barrier layer 113 is disposed between the high-mobility film layer and the low-mobility film layer. In the top gate structure, the first semiconductor layer 111 in the active layer 11 is a low-mobility film layer, the second semiconductor layer 112 is a high-mobility film layer, and the first barrier layer 113 is disposed between the low-mobility film layer and the high-mobility film layer. Thus, by providing both the high-mobility film layer and the low-mobility film layer and disposing the low-mobility film layer between the high-mobility film layer and the gate electrode (the top gate in the top gate structure), a double channel may be formed, so as to make a threshold voltage (Vth) positive and improve a mobility rate.

Exemplarily, each of the first semiconductor layer 111 and the second semiconductor layer 112 may be a metal oxide semiconductor. The metal oxide may include, but is not limited to, indium gallium zinc oxide (IGZO), indium gallium tin oxide (IGTO), indium gallium oxide (IGO), indium zinc oxide (IZO), aluminum indium zinc oxide (AIZO), aluminum tin zinc oxide (ATZO), and the like. The material of the first semiconductor layer 111 and the material of the second semiconductor layer 112 may be the same or different from each other, which is not specifically limited in the present disclosure.

In some embodiments, the active layer 11 of the thin film transistor 1 is a multi-layer structure. The multi-layer structure may include more than two layers of semiconductor layers, or only include the first semiconductor layer 111 and the second semiconductor layer 112. The semiconductor layer may include two layers, three layers, four layers, five layers, six layers, and more. The active layer 11 of the thin film transistor 1 is preferably formed by stacking a first semiconductor layer 111, a first barrier layer 113 and a second semiconductor layer 112 in layers, in order to simplify the structure of the active layer 11 of the thin film transistor 1 and a preparation process of the thin film transistor 1, thereby reducing a manufacturing cost of a display substrate.

In some embodiments, both the first semiconductor layer 111 and the second semiconductor layer 112 may be made of IGZO, which has a good stability. A threshold voltage Vth of the thin film transistor 1 may be made positive by designing mobility rates of the first semiconductor layer 111 and the second semiconductor layer 112, so that the mobility rate of the thin film transistor 1 is improved, while stability of performance of the thin film transistor 1 is ensured.

Exemplarily, a thickness of the active layer 11 may range from 10 nm to 100 nm. For example, the thickness of the active layer 11 may be configured to be 10 nm, 30 nm, 50 nm, 80 nm, 100 nm, or the like. The thickness of the active layer 11 is not limited to listed values, and other unlisted values in the range are also applicable.

Exemplarily, the thin film transistor 1 may include at least one of a driving thin film transistor and a switching thin film transistor. The structure of the thin film transistor 1 may include at least one of a bottom gate structure, a top gate structure, and a dual-gate structure. A type of the thin film transistor is not specifically limited in the present disclosure.

Exemplarily, a substrate of the thin film transistor 1 may be a glass substrate, a ceramic substrate, a quartz substrate, or a sapphire substrate. In addition, a single crystal semiconductor substrate or a polycrystalline semiconductor substrate made of silicon or silicon carbide, a compound semiconductor substrate made of silicon germanium, a silicon on insulator (SOI) substrate, and the like may alternatively be used as the substrate. Moreover, a substrate provided with a semiconductor element may alternatively be used as the substrate. The material of the substrate is not specifically limited in the present disclosure.

Exemplarily, the active layer 11 of the thin film transistor 1 may include at least one of amorphous silicon, low-temperature polycrystalline silicon, single-crystal silicon, and an oxide semiconductor. The material of the active layer 11 is not specifically limited in the present disclosure.

Exemplarily, the buffer layer 15 may include, but is not limited to, a silicon oxide layer, a silicon nitride layer, a silicon oxynitride layer, or stacked layers of the silicon nitride layer and the silicon oxide layer.

Exemplarily, a material of the first gate insulation layer 13 may include, but is not limited to, at least one of silicon oxide, aluminum oxide, and silicon nitride.

Exemplarily, a material of the gate electrode 2 may include, but is not limited to, at least one of molybdenum, aluminum, copper, titanium, indium zinc oxide, and indium tin oxide.

According to the thin film transistor provided by the embodiment of the present disclosure, the active layer 11 is a multilayer with the first semiconductor layer 111 and the second semiconductor layer 112 stacked. The first semiconductor layer 111 is located on a side, away from the substrate 10, of the second semiconductor layer 112, and a mobility rate of the first semiconductor layer 111 is less than the mobility rate of the second semiconductor layer 112. Thus, the first semiconductor layer 111 with a low mobility rate may protect the second semiconductor layer 112 with a high mobility rate. Meanwhile, a double channel may be formed, so that the threshold voltage (Vth) may be made positive and a mobility rate of the thin film transistor 1 may be improved. After the mobility rate of the thin film transistor 1 is improved, a larger processing Margin may be accommodated to ensure device stability. In addition, the first barrier layer 113 is introduced between the first semiconductor layer 111 and the second semiconductor layer 112 to prevent instability of an interface due to mutual diffusion of elements between the first semiconductor layer 111 and the second semiconductor layer 112, so that inability of achieving a high mobility rate may be solved.

In some embodiments, as shown in FIG. 4, an orthographic projection of the first barrier layer 113 on the substrate 10 covers an orthographic projection of the first semiconductor layer 111 on the substrate 10. The orthographic projection of the first barrier layer 113 on the substrate 10 covers an orthographic projection of the second semiconductor layer 112 on the substrate 10. Thus, diffusion of elements at a high temperature may be suppressed, thereby ensuring a clear channel interface, and effectively achieving a multi-channel effect.

Specifically, an area of the orthographic projection of the first barrier layer 113 on the base 10 is equal to an area of the orthographic projection of the first semiconductor layer 111 on the substrate 10 and/or an area of the orthographic projection of the second semiconductor layer 112 on the substrate 10.

In some other embodiments, the area of the orthographic projection of the first barrier layer 113 on the substrate 10 may alternatively be greater than the area of the orthographic projection of the first semiconductor layer 111 on the substrate 10 and/or the area of the orthographic projection of the second semiconductor layer 112 on the substrate 10.

FIG. 5 is a schematic structural diagram of an active layer according to another embodiment of the present disclosure. As shown in FIG. 5, the active layer 11 may further include a second barrier layer 114, and the second barrier layer 114 is provided between the second semiconductor layer 112 and the substrate 10.

Exemplarily, an orthographic projection of the second barrier layer 114 on the substrate 10 covers an orthographic projection of the second semiconductor layer 112 on the substrate 10. That is, an area of the orthographic projection of the second barrier layer 114 on the substrate 10 is greater than or equal to an area of the orthographic projection of the second semiconductor layer 112 on the substrate 10.

The second barrier layer 114 is disposed between the second semiconductor layer 112 and the substrate 10. The second barrier layer 114 is configured to block an element in the second semiconductor layer 112 diffused from the substrate 10.

According to the thin film transistor provided by the embodiment of the present disclosure, the active layer 11 includes the first barrier layer 113 and the second barrier layer 114. The first barrier layer 113 is disposed between a first semiconductor layer 111 and a second semiconductor layer 112. The second barrier layer 114 is disposed between the second semiconductor layer 112 and the substrate 10. The first barrier layer 113 and the second barrier layer 114 form a double-layer barrier structure, so that an upper side and a lower side of the second semiconductor layer 112 are protected by barrier layers. Thus, diffusion of elements in the second semiconductor layer 112 at a high temperature may be effectively prevented, thereby ensuring stability of a channel interface and achieving a high mobility rate of the thin film transistor 1.

In some embodiments of the present disclosure, the thin film transistor 1 is a dual-gate structure or a top gate structure. A first semiconductor layer 111 is a low-mobility film layer, and a second semiconductor layer 112 is a high-mobility film layer. Each of the first semiconductor layer 111 and the second semiconductor layer 112 includes a metal element, and an atomic ratio of the metal element in the first semiconductor layer 111 is less than an atomic ratio of the metal element in the second semiconductor layer 112. The atomic ratio refers to a ratio of quantities of atoms of different elements contained in the film layer.

Exemplarily, a type of the metal element in the first semiconductor layer 111 is the same as a type of the metal element of the second semiconductor layer 112.

For example, each of the first semiconductor layer and the second semiconductor layer includes a first metal element and a second metal element, and an atomic ratio of the first metal element to the second metal element in the first semiconductor layer is less than an atomic ratio of the first metal element to the second metal element in the second semiconductor layer, so that a mobility rate of the first semiconductor layer is less than a mobility rate of the second semiconductor layer. Therein, the first metal element may be indium (In), and the second metal element may be gallium (Ga).

Specifically, each of the first semiconductor layer 111 and the second semiconductor layer 112 is an IGZO semiconductor layer, and the IGZO semiconductor layer includes three metal elements of indium (In), gallium (Ga), and zinc (Zn). An In:Ga ratio of the first semiconductor layer 111 is less than an In:Ga ratio of the second semiconductor layer 112. That is, a ratio of a quantity of atoms of In to a quantity of atoms of Ga in the first semiconductor layer 111 is less than a ratio of a quantity of atoms of In to a quantity of atoms of Ga in the second semiconductor layer 112. A threshold voltage of the thin film transistor 1 is positive, but the mobility rate of the first semiconductor layer 112 is low. The first semiconductor layer 111 is a low-mobility channel layer of multiple channels. In the first semiconductor layer 111, an atomic percentage content of indium ranges from 30% to 50%, an atomic percentage content of gallium ranges from 10% to 40%, and an atomic percentage content of zinc ranges from 10% to 40% relative to the amount of cations included in the first semiconductor layer 111. For example, in the first semiconductor layer 111, the atomic percentage content of indium may be 30%, 40%, 45%, 50%, and the like, the atomic percentage content of gallium may be 10%, 20%, 30%, 40%, and the like, and the atomic percentage content of zinc may be 10%, 20%, 30%, 40%, and the like. The atomic percentage content of indium (In), gallium (Ga), and zinc (Zn) in the first semiconductor layer 111 is not limited to the listed values, and other unlisted values in the range are alternatively applicable. Of course, other values outside the above range may alternatively be configured according to an actual situation. The In:Ga ratio of the second semiconductor layer 112 is greater than the In:Ga ratio of the first semiconductor layer 111, so that the mobility rate of the second semiconductor layer 112 is higher. However, the In element is easy to diffuse at a high temperature, and the second semiconductor layer 112 is a high-mobility channel layer of multiple channels.

In the second semiconductor layer 112, an atomic percentage content of indium ranges from 50% to 90%, an atomic percentage content of gallium ranges from 5% to 20%, and an atomic percentage content of zinc ranges from 5% to 30% relative to the amount of cations included in the second semiconductor layer 112. The atomic percent content is a percentage of a quantity of a certain type of atom of an element to a sum of quantities of atoms of all elements in a compound. For example, in the second semiconductor layer 112, the atomic percentage content of indium may be 50%, 60%, 70%, 90%, and the like, the atomic percentage content of gallium may be 5%, 10%, 15%, 20%, and the like, and the atomic percentage content of zinc may be 5%, 10%, 20%, 30%, and the like. The atomic percentage content of indium (In), gallium (Ga), and zinc (Zn) in the second semiconductor layer 112 is not limited to the listed values, and other unlisted values in the range are alternatively applicable. Of course, other values outside the above range may alternatively be configured according to an actual situation.

In some embodiments, a process of atomic layer deposition (ALD) may be used to prepare the first semiconductor layer 111 and the second semiconductor layer 112, thereby achieving formation of oxide films stacked in layers. Meanwhile, an atomic ratio of the film formed by ALD may be controlled according to a requirement of the atomic ratio. Of course, a process of physical vapor deposition (PVD) may alternatively be used.

According to the thin film transistor provided by the embodiment of the present disclosure, the atomic ratio of the metal element in the first semiconductor layer 111 is less than the atomic ratio of the metal element in the second semiconductor layer 112, so that the mobility rate of the first semiconductor layer 111 is less than the mobility rate of the second semiconductor layer 112, thereby facilitating construction of a multi-layer semiconductor layer with multiple channels. Meanwhile, stability of the device, processing Margin, and multi-channel transport may be considered at the same time.

In some embodiments of the present disclosure, the thin film transistor 1 is a bottom gate structure. The first semiconductor layer 111 is a high-mobility film layer, and the second semiconductor layer 112 is a low-mobility film layer. An atomic ratio of the metal element in the first semiconductor layer 111 is greater than an atomic ratio of a metal element in the second semiconductor layer 112.

Specifically, each of the first semiconductor layer 111 and the second semiconductor layer 112 is an IGZO semiconductor layer. The IGZO semiconductor layer includes three metal elements of indium (In), gallium (Ga), and zinc (Zn). An In:Ga ratio of the first semiconductor layer 111 is greater than an In:Ga ratio of the second semiconductor layer 112. That is, a ratio of a quantity of atoms of In to a quantity of atoms of Ga in the first semiconductor layer 111 is greater than a ratio of a quantity of atoms of In to a quantity of atoms of Ga in the second semiconductor layer 112. The first semiconductor layer 111 is a high-mobility channel layer of multiple channels. In the first semiconductor layer 111, an atomic percentage content of indium ranges from 50% to 90%, an atomic percentage content of gallium ranges from 5% to 20%, and an atomic percentage content of zinc ranges from 5% to 30% relative to the amount of cations included in the first semiconductor layer 111. The In:Ga ratio of the second semiconductor layer 112 is less than the In:Ga ratio of the first semiconductor layer 111, and the second semiconductor layer 112 is a low-mobility channel layer of multiple channels. In the second semiconductor layer 112, an atomic percentage content of indium ranges from 30% to 50%, an atomic percentage content of gallium ranges from 10% to 40%, and an atomic percentage content of zinc ranges from 10% to 40% relative to the amount of cations included in the second semiconductor layer 112.

In an embodiment of the present disclosure, each of the first barrier layer 113, the second barrier layer 114, the first semiconductor layer 111, and the second semiconductor layer 112 includes at least one metal element. A quantity of types of metal elements in the first barrier layer 113 is less than a quantity of types of metal elements in the first semiconductor layer 111 and/or the second semiconductor layer 112. A quantity of types of metal elements in the second barrier layer 114 is less than the quantity of types of metal elements in the first semiconductor layer 111 and/or the second semiconductor layer 112.

Exemplarily, the quantity of types of metal elements in the first barrier layer 113 is equal to the quantity of types of metal elements in the second barrier layer 114.

Exemplarily, the metal element in each of the first barrier layer 113 and the second barrier layer 114 includes at least one of gallium and zinc.

Exemplarily, an atomic percentage content of gallium in each of the first barrier layer 113 and the second barrier layer 114 ranges from 30% to 100%, and an atomic percentage content of zinc in each of the first barrier layer 113 and the second barrier layer 114 ranges from 0% to 70%.

Exemplarily, in the first barrier layer 113 and the second barrier layer 114, the atomic percentage contents of gallium may be 30%, 50%, 60%, 70%, 90%, 100%, and the like, and the atomic percentage content of zinc may be 5%, 10%, 15%, 20%, 30%, 50%, 60%, 70%, and the like. However, the atomic percentage content of gallium and zinc in the first barrier layer 113 and the atomic percentage content of gallium and zinc in the second barrier layer 114 is not limited to the listed values, and other unlisted values in the range thereof are alternatively applicable. Of course, other values outside the above range may alternatively be configured according to an actual situation.

Exemplarily, both the first barrier layer 113 and the second barrier layer 114 may be made of In-free GZO or gallium oxide (GaOx).

According to the thin film transistor provided by the embodiment of the present disclosure, the quantity of types of metal elements in both the first barrier layer 113 and the second barrier layer 114 is less than the quantity of types of metal elements in the first semiconductor layer 111 or the quantity of types of metal elements in the second semiconductor layer 112, so that a band gap of both the first barrier layer 113 and the second barrier layer 114 is large. Meanwhile, the first barrier layer 113 and the second barrier layer 114 basically do not participate in conduction, thereby effectively isolating the first semiconductor layer 111 and the second semiconductor layer 112.

FIG. 6 is a schematic structural diagram of an active layer according to still another embodiment of the present disclosure. As shown in FIG. 6, an active layer 11 may further include a third semiconductor layer 115, and the third semiconductor layer 115 is disposed between a second barrier layer 114 and a substrate 10.

In some embodiments, a mobility rate of the third semiconductor layer 115 may be equal to a mobility rate of the first semiconductor layer 111. The mobility rate of the third semiconductor layer 115 may alternatively be less than or greater than the mobility rate of the first semiconductor layer 111.

Exemplarily, a material of the third semiconductor layer 115 may be a metal oxide semiconductor material. The metal oxide semiconductor material may include, but is not limited to, indium gallium zinc oxide (IGZO), indium gallium tin oxide (IGTO), indium gallium oxide (IGO), indium zinc oxide (IZO), aluminum indium zinc oxide (AIZO), or aluminum tin zinc oxide (ATZO). The material of the third semiconductor layer 115 may be the same as or different from a material of the first semiconductor layer 111 or a material of the second semiconductor layer 112, which is not limited by the present disclosure.

In some embodiments, each of the first semiconductor layer 111, the second semiconductor layer 112, and the third semiconductor layer 115 may be made of IGZO. The active layer 11 is a stacked multi-layer structure. A barrier layer is disposed between every two adjacent semiconductor layers. That is, a first barrier layer 113 is disposed between a first semiconductor layer 111 and a second semiconductor layer 112, and a second barrier layer 114 is disposed between the second semiconductor layer 112 and a third semiconductor layer 115.

According to the thin film transistor provided by the embodiment of the present disclosure, the third semiconductor layer 115 is disposed between the second barrier layer 114 and the substrate 10. The mobility rate of the third semiconductor layer 115 is equal to the mobility rate of the first semiconductor layer 111. The active layer 11 is formed as a multi-layer structure with multiple channels. By constructing the multiple channels through low-mobility/high-mobility/low-mobility IGZO semiconductor layers, the device may be more stable, and a processing Margin may be greater. In addition, by providing a barrier layer between every two adjacent layers of semiconductor layers, diffusion between elements may be prevented, thereby avoiding a problem of instability of an interface and inability of achieving a high mobility rate.

In an embodiment of the present disclosure, each of the third semiconductor layer 115 and the second semiconductor layer 112 includes a metal element. An atomic ratio of the metal element in the third semiconductor layer 115 is less than an atomic ratio of the metal element in the second semiconductor layer 112.

For example, each of the third semiconductor layer and the second semiconductor layer includes a first metal element and a second metal element, and an atomic ratio of the first metal element to the second metal element in the third semiconductor layer is less than an atomic ratio of the first metal element to the second metal element in the second semiconductor layer, so that a mobility rate of the third semiconductor layer is less than a mobility rate of the second semiconductor layer. Therein, the first metal element may be indium (In), and the second metal element may be gallium (Ga).

Exemplarily, the third semiconductor layer 115 is an IGZO semiconductor layer, and the third semiconductor layer 115 includes three metal elements of indium (In), gallium (Ga), and zinc (Zn). An In:Ga ratio of the third semiconductor layer 115 is less than an In:Ga ratio of the second semiconductor layer 112. A threshold voltage of the thin film transistor 1 is positive, but a mobility rate of the third semiconductor layer 115 is low. Each of the third semiconductor layer 115 and the first semiconductor layer 111 is a low-mobility channel layer of multiple channels.

Exemplarily, in the third semiconductor layer, an atomic percentage content of indium 115 ranges from 30% to 50%, an atomic percentage content of gallium ranges from 10% to 40%, and an atomic percentage content of zinc ranges from 10% to 40% relative to the amount of cations included in the third semiconductor layer 115. For example, in the third semiconductor layer 115, the atomic percentage content of indium may be 30%, 40%, 45%, 50%, and the like, the atomic percentage content of gallium may be 10%, 20%, 30%, 40%, and the like, and the atomic percentage content of zinc may be 10%, 20%, 30%, 40%, and the like. The atomic percentage content of indium, gallium and zinc in the third semiconductor layer 115 is not limited to the listed values, and other unlisted values in the range are alternatively applicable. Of course, other values outside the above range may alternatively be configured according to an actual situation.

According to the thin film transistor provided by the embodiment of the present disclosure, by constructing multiple channels through low-mobility/high-mobility/low-mobility IGZO semiconductor layers, the active layer 11 is formed as a multi-layer structure with multiple channels with the first semiconductor layer 111, the second semiconductor layer 112 and the third semiconductor layer 115 stacked in layers, so that a multi-channel transport interface is effectively constructed, thereby achieving advantages including a greater processing Margin, better illumination stability, multi-channel transport, and the like.

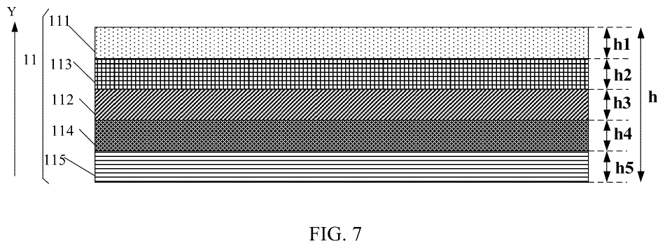

FIG. 7 is a schematic structural diagram of an active layer according to still another embodiment of the present disclosure. As shown in FIG. 7, in a direction from a substrate 10 to an active layer 11 (Y direction in FIG. 7), a thickness H of the active layer 11 ranges from 10 nm to 100 nm. Preferably, the thickness H of the active layer 11 ranges from 10 nm to 70 nm.

Exemplarily, a thickness H1 of the first semiconductor layer 111 ranges from 1 nm to 20 nm.

Exemplarily, a thickness H3 of the second semiconductor layer 112 ranges from 1 nm to 20 nm.

Exemplarily, a thickness H5 of the third semiconductor layer 115 ranges from 1 nm to 20 nm.

Exemplarily, a thickness H2 of the first barrier layer 113 ranges from 1 nm to 5 nm.

Exemplarily, a thickness H4 of the second barrier layer 114 ranges from 1 nm to 5 nm.

The thicknesses of the first semiconductor layer 111, the thicknesses of the second semiconductor layer 112, and the thicknesses of the third semiconductor layer 115 may be the same or different from each other. The thickness of the first barrier layer 113 may be greater than or equal to the thickness of the first semiconductor layer 111 or the thickness of the second semiconductor layer 112 or the thickness of the third semiconductor layer 115. The thickness of each film layer is not specifically limited in the present disclosure, and may be configured according to an actual situation.

An embodiment of the present disclosure provides a display panel. The display panel includes: a substrate base; and a plurality of pixel units disposed on the substrate base. Each pixel unit includes a pixel circuit, and the pixel circuit includes the thin film transistor in any embodiments mentioned above.

Specifically, each pixel unit of the display panel may be equipped with a pixel circuit. The pixel circuit may include a thin film transistor having a switching function (that is, a switching transistor), a thin film transistor having a driving function (that is, a driving transistor), and a charge storage capacitor. In addition, the pixel circuit may further include other types of thin film transistors having a compensation function.

A quantity of the thin film transistors may be 2, 4, or more. The quantity of the thin film transistors is not specifically limited in the present disclosure. The plurality of thin film transistors may be stacked in layers.

According to the display panel provided by the embodiment of the present disclosure, an active layer of the thin film transistor is a multi-layer structure including a first semiconductor layer and a second semiconductor layer stacked in layers. The first semiconductor layer is located on a side, away from a substrate, of the second semiconductor layer, and a mobility rate of the first semiconductor layer is less than a mobility rate of the second semiconductor layer. Thus, the first semiconductor layer with a low mobility rate may protect the second semiconductor layer with a high mobility rate. Meanwhile, a double channel may be formed, so that a threshold voltage (Vth) may be made positive and a mobility rate of the thin film transistor may be improved. After the mobility rate of the thin film transistor is improved, a larger processing Margin may be accommodated to ensure device stability. In addition, a first barrier layer is introduced between the first semiconductor layer and the second semiconductor layer to prevent instability of an interface due to mutual diffusion of elements between the first semiconductor layer and the second semiconductor layer, so that inability of achieving a high mobility rate may be solved, thereby further improving yield and reliability of the display panel.

An embodiment of the present disclosure provides a display apparatus. The display apparatus includes the display panel in any embodiment mentioned above.

Exemplarily, the display panel may be a rigid display panel, or may be a flexible display panel (that is, bendable and foldable). The display panel may be a liquid crystal display panel of a twisted nematic (TN) type, a vertical alignment (VA) type, an in-plane switching (IPS) type, an advanced super dimensional switch (ADS) type, or the like. Alternatively, the display panel may be an organic light-emitting diode (OLED) display panel, or may be a Micro LED display panel or a Mini LED display panel. The type of the display panel is not limited herein.

The display panel may be applied to the display apparatus. The display apparatus may be any product or component having a display function, such as a mobile terminal, a tablet computer, a computer display, a television, a wearable device, or an information query machine. The display apparatus includes the display panel according to any embodiment of the present disclosure. Technical principle and resulting effects of the display apparatus are similar to those of the display panel, and are not be repeated here.

According to the display apparatus provided by the embodiment of the present disclosure, an active layer of the thin film transistor is a multi-layer structure including a first semiconductor layer and a second semiconductor layer stacked in layers. The first semiconductor layer is located on a side, away from a substrate, of the second semiconductor layer, and a mobility rate of the first semiconductor layer is less than a mobility rate of the second semiconductor layer. Thus, the first semiconductor layer with a low mobility rate may protect the second semiconductor layer with a high mobility rate. Meanwhile, a double channel may be formed, so that a threshold voltage (Vth) may be made positive and a mobility rate of the thin film transistor may be improved. After the mobility rate of the thin film transistor is improved, a larger processing Margin may be accommodated to ensure device stability. In addition, a first barrier layer is introduced between the first semiconductor layer and the second semiconductor layer to prevent instability of an interface due to mutual diffusion of elements between the first semiconductor layer and the second semiconductor layer, so that inability of achieving a high mobility rate may be solved, thereby further improving yield and reliability of the display panel.

The basic principle of the present disclosure is described above with reference to specific embodiments, but it should be noted that advantages, benefits, effects, and the like mentioned in the present disclosure are only examples and not limitations. The advantages, benefits, effects, and the like cannot be considered as necessary for various embodiments of the present disclosure. In addition, the specific details disclosed above are only for the purpose of illustration and ease of understanding, and not for limitation. The above details do not limit the present disclosure to necessarily adopt the specific details mentioned above for implementation.

The block diagrams of the means, apparatuses, devices and systems involved in the present disclosure are merely illustrative examples and are not intended to require or imply that connections, arrangements, and configurations must be made in the manner shown in block diagrams. As those skilled in the art will recognize, the means, apparatuses, devices, systems may be connected, arranged, configured in any manner. The words such as “comprise”, “include”, “have” . . . are open words, refer to “including but not limited to”, and may be used interchangeably. The words “or” and “and” as used herein refer to the word “and/or”, and may be used interchangeably, unless the context clearly indicates otherwise. The term “such as” used herein refers to the phrase “such as, but not limited to,” and may be used interchangeably therewith.

It should further be noted that, in the apparatus, device, and method of the present disclosure, each component or each step may be decomposed and/or recombined. These decomposition and/or recombination should be considered as equivalent solutions of the present disclosure.

The previous description of the disclosed aspects is provided to enable any person skilled in the art to make or use the present disclosure. Various modifications to these aspects will be readily apparent to those skilled in the art, and the generic principles defined herein may be applied to other aspects without departing from the scope of the present disclosure. Thus, the present disclosure is not intended to be limited to the aspects shown herein but is to be accorded the widest scope consistent with the principles and novel features disclosed herein.

The foregoing description has been presented for purposes of illustration and description. Moreover, the description is not intended to limit the embodiments of the present disclosure to the forms disclosed herein. While various example aspects and embodiments have been discussed above, those skilled in the art will recognize certain variations, modifications, changes, additions, and sub-combinations thereof.

What is claimed is:

1. A thin film transistor, comprising:
a substrate; and
an active layer provided on the substrate, wherein the active layer comprises a first semiconductor layer, a first barrier layer, and a second semiconductor layer stacked in sequence, the first semiconductor layer is located on a side, away from the substrate, of the second semiconductor layer, and a mobility rate of the first semiconductor layer is less than a mobility rate of the second semiconductor layer.

2. The thin film transistor according to claim 1, wherein an orthographic projection of the first barrier layer on the substrate covers an orthographic projection of the first semiconductor layer on the substrate, and the orthographic projection of the first barrier layer on the substrate covers an orthographic projection of the second semiconductor layer on the substrate.

3. The thin film transistor according to claim 1, wherein the active layer further comprises a second barrier layer, and the second barrier layer is provided between the second semiconductor layer and the substrate.

4. The thin film transistor according to claim 3, wherein an orthographic projection of the second barrier layer on the substrate covers an orthographic projection of the second semiconductor layer on the substrate.

5. The thin film transistor according to claim 1, wherein each of the first semiconductor layer and the second semiconductor layer comprises a first metal element and a second metal element, and an atomic ratio of the first metal element to the second metal element in the first semiconductor layer is less than an atomic ratio of the first metal element to the second metal element in the second semiconductor layer.

6. The thin film transistor according to claim 5, wherein types of metal elements in the first semiconductor layer are the same as types of metal elements in the second semiconductor layer.

7. The thin film transistor according to claim 6, wherein the metal elements in each of the first semiconductor layer and the second semiconductor layer comprise at least one of indium, gallium and zinc.

8. The thin film transistor according to claim 7, wherein in the first semiconductor layer, an atomic percentage content of indium ranges from 30% to 50%, an atomic percentage content of gallium ranges from 10% to 40%, and an atomic percentage content of zinc ranges from 10% to 40%; and
in the second semiconductor layer, an atomic percentage content of indium ranges from 50% to 90%, an atomic percentage content of gallium ranges from 5% to 20%, and an atomic percentage content of zinc ranges from 5% to 30%.

9. The thin film transistor according to claim 8, wherein one of materials of each of the first semiconductor layer and the second semiconductor layer comprises a metal oxide semiconductor material.

10. The thin film transistor according to claim 3, wherein each of the first barrier layer, the second barrier layer, the first semiconductor layer and the second semiconductor layer comprises at least one metal element, a quantity of types of metal elements in the first barrier layer is less than a quantity of types of metal elements in the first semiconductor layer or the second semiconductor layer, and a quantity of types of metal elements in the second barrier layer is less than the quantity of types of metal elements in the first semiconductor layer or the second semiconductor layer.

11. The thin film transistor according to claim 10, wherein the quantity of types of metal elements in the first barrier layer is equal to the quantity of types of metal elements in the second barrier layer;
metal elements in each of the first barrier layer and the second barrier layer comprise at least one of gallium and zinc; and
an atomic percentage content of gallium in each of the first barrier layer and the second barrier layer ranges from 30% to 100%, and an atomic percentage content of zinc in each of the first barrier layer and the second barrier layer ranges from 0% to 70%.

12. The thin film transistor according to claim 3, wherein the active layer further comprises a third semiconductor layer, and the third semiconductor layer is provided between the second barrier layer and the substrate; and
a mobility rate of the third semiconductor layer is equal to the mobility rate of the first semiconductor layer.

13. The thin film transistor according to claim 12, wherein each of the third semiconductor layer and the second semiconductor layer comprises at least one metal element, and an atomic ratio of the metal element in the third semiconductor layer is less than an atomic ratio of the metal element in the second semiconductor layer.

14. The thin film transistor according to claim 13, wherein the metal element in each of the third semiconductor layer and the first semiconductor layer comprises at least one of indium, gallium and zinc;
in the third semiconductor layer, an atomic percentage content of indium ranges from 30% to 50%, an atomic percentage content of gallium ranges from 10% to 40%, and an atomic percentage content of zinc ranges from 10% to 40%; and
one of materials of the third semiconductor layer comprises a metal oxide semiconductor material.

15. The thin film transistor according to claim 1, wherein in a direction from the substrate to the active layer, a thickness of the active layer ranges from 10 nm to 100 nm;
a thickness of the first semiconductor layer ranges from 1 nm to 20 nm;
a thickness of the second semiconductor layer ranges from 1 nm to 20 nm; and
a thickness of the first barrier layer ranges from 1 nm to 5 nm.

16. The thin film transistor according to claim 1, wherein the thin film transistor is a top gate structure or a dual-gate structure.

17. A thin film transistor, comprising:
a substrate; and
an active layer provided on the substrate, wherein the active layer comprises a first semiconductor layer, a first barrier layer, and a second semiconductor layer stacked in sequence, the first semiconductor layer is located on a side, away from the substrate, of the second semiconductor layer, and a mobility rate of the second semiconductor layer is less than a mobility rate of the first semiconductor layer; and
the thin film transistor is a bottom gate structure.

18. The thin film transistor according to claim 17, wherein an orthographic projection of the first barrier layer on the substrate covers an orthographic projection of the first semiconductor layer on the substrate, and the orthographic projection of the first barrier layer on the substrate covers an orthographic projection of the second semiconductor layer on the substrate.

19. A display panel, comprising:
a substrate base; and
a plurality of pixel units provided on the substrate base, wherein the pixel unit comprises a pixel circuit, and the pixel circuit comprises the thin film transistor according to claim 1.

20. A display apparatus, comprising the display panel according to claim 19.
